(19) United States
(12) Patent Application Publication
(10) Pub. No.: US 2013/0160832 A1
(43) Pub. Date: Jun. 27, 2013

(54) MARKING OF A SUBSTRATE OF A SOLAR CELL

(71) Applicants: Andreas Krause, Radebeul (DE); Frank Martin, Neukirchen (DE); Grit Bonsdorf, Dresden (DE); Matthias Georgi, Dresden (DE); Bernd Scheibe, Dresden (DE); Matthias Wagner, Freiberg (DE)

(72) Inventors: Andreas Krause, Radebeul (DE); Frank Martin, Neukirchen (DE); Grit Bonsdorf, Dresden (DE); Matthias Georgi, Dresden (DE); Bernd Scheibe, Dresden (DE); Matthias Wagner, Freiberg (DE)

(21) Appl. No.: 13/335,370

(22) Filed: Dec. 22, 2011

(51) Int. Cl. H01L 31/18; H01L 31/0236

(52) U.S. Cl. 136/256; 438/57; 257/E31.032

(57) ABSTRACT

The present invention relates to a solar-cell-marking method. The method comprises providing a substrate for a solar cell, forming an etching mask on the substrate, and carrying out an etching process, wherein an elevated marking structure defined by the etching mask is formed on the substrate. The invention further relates to a solar cell comprising such a marking structure.

### FIELD

The present invention relates to a solar-cell-marking method in which an elevated marking structure is formed on a substrate of a solar cell. The invention further relates to a solar cell comprising such a marking structure.

### BACKGROUND

Solar cells are used to convert electromagnetic radiation energy, typically sunlight, into electrical energy. The energy conversion is based on radiation being subject to an absorption in a solar cell, thus generating positive and negative charge carriers (“electron-hole pairs”). The generated free charge carriers are furthermore separated from each other in order to be discharged via separate contacts. In a solar module, a plurality of solar cells operating in accordance with this functional principle are generally combined.

Conventional solar cells are manufactured from semiconductor substrates or wafers, respectively, which are subjected to a range of different processes. Furthermore, the solar-cell substrates are usually provided with a marking structure, thus allowing for identification and traceability of the solar cells during as well as after manufacture up to the finished solar module. Such a marking, which is also referred to as “code” or, respectively, “wafer code” is usually configured in the form of recesses in a substrate surface.

KR 1020090044082 A and KR 1020090037171 A disclose methods for marking a semiconductor substrate in which a substrate surface is coated by means of a photoresist, the photoresist being subsequently structured or, respectively, removed at defined locations in order to expose the substrate surface. In a subsequent etching process, substrate material is removed at the exposed locations of the substrate surface, thus forming recesses in order to mark the substrate. In the former document, structuring of the photoresist is effected by exposing and developing, and in the latter document by irradiating by means of a laser. In order to achieve that within the framework of the etching method a removal of substrate material is only carried out in the area of the recesses to be produced and intended as markings, and etching of the substrate surface is avoided in other locations, such methods require large-area deposition of photoresist on the substrate surface.

In other known marking methods, recesses are “burnt” or, respectively, “written” into a substrate surface directly by means of a laser beam, which is also referred to as “laser marking”. In this respect, U.S. Pat. No. 6,743,694 B2 discloses that a substrate is provided with differing layers and that material of the layers and of the substrate are subsequently removed by means of a laser beam in order to generate recesses. EP 1 989 740 B1 describes a solar-cell-marking method in which recesses serving as marking are provided in a semiconductor substrate by means of a laser beam at the beginning of solar cell production.

### SUMMARY

Various aspects of the present invention provide an improved method for marking a substrate of a solar cell and a solar cell comprising such a marking.

One embodiment of the present invention provides a solar-cell-marking method. The method comprises providing a substrate for a solar cell, forming an etching mask on the substrate, and carrying out an etching process, wherein an elevated marking structure defined by the etching mask is formed on the substrate.

Another embodiment of the present invention provides a solar cell comprising a substrate and an elevated marking structure on the substrate, formed by carrying out an etching process by means of an etching mask formed on the substrate.

### BRIEF DESCRIPTION OF THE DRAWINGS

These and other features of the present invention will become clear from the following description taken in conjunction with the accompanying drawings. It is to be noted, however, that the accompanying drawings illustrate only typical embodiments of the present invention and are, therefore not to be considered limiting of the scope of the invention. The present invention may admit other equally effective embodiments.

FIG. 1 shows a direct deposition of an etching mask on a substrate of a solar cell by means of a jet-printing process;

FIG. 2 shows a direct deposition of an etching mask on the substrate by means of a foil-transfer process;

FIGS. 3 to 5 illustrate an indirect deposition of an etching mask on the substrate by depositing and structuring an etching-mask layer;

FIG. 6 depicts a forming of an elevated marking structure on the substrate by means of an etching process using an etching mask;

FIG. 7 shows the substrate comprising the elevated marking structure after removing the etching mask;

FIG. 8 depicts a removal of the etching mask from the substrate by means of a laser beam;

FIG. 9 shows a solar cell comprising the substrate with the elevated marking structure;

FIG. 10 shows a flow chart for illustrating steps of a method for manufacturing a solar cell, within the framework of which a marking of a substrate of the solar cell is carried out;

FIGS. 11 and 12 depict a forming of an elevated marking structure on the substrate by means of an unstructured etching-mask layer; and

FIGS. 13 to 15 show a forming of an inverse elevated marking structure on the substrate by means of an etching process using an inverse etching mask.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The present invention provides a solar-cell-marking method. The method comprises providing a substrate for a solar cell, forming an etching mask on the substrate and carrying out an etching process, wherein an elevated marking structure defined by the etching mask is formed on the substrate.

In the solar-cell-marking method which may be carried out within the framework of manufacturing a solar cell in order to allow for e.g. identifying and tracing the solar cell or, respectively, the associated substrate, an elevated marking structure is formed on the substrate by means of etching. Such a marking structure may be generated in a simple and inexpensive manner. At this, forming the elevated marking structure may be carried out by means of a locally limited etching mask generated in a partial area of a surface of the substrate, and not by large-area coating of the substrate. Moreover, the elevated marking structure may be rendered visible more easily and thus more recognizable compared to a conventional marking structure consisting exclusively of recesses in a substrate surface. Furthermore, the etching mask deposited on the substrate, which may have a shape or, respectively, a structure corresponding to the marking structure may also be used to identify the substrate.

The elevated marking structure (as well as the etching mask, as the case may be) may not only be a marking provided for identification, but any kind of marking. For example, a configuration or, respectively, use as an alignment mark is conceivable, as well, by means of which various processes may be adjusted or, respectively, various process levels may be aligned with respect to one another.

In a possible embodiment, the method further comprises removing the etching mask. Thereby, it may be avoided that etching mask material causes a contamination of the substrate in a subsequent process.

Different processes may be used for removing the etching mask, e.g. a high-temperature step for thermally removing the etching mask or chemical removal by means of a solvent may be carried out. In an alternative embodiment, removal of the etching mask is carried out by irradiating the etching mask with a laser beam. The laser beam may in this context be used only locally or, respectively, in the area of the etching mask, thus allowing for a relatively quick removal of the etching mask. This procedure also allows for avoiding thermal stress on the (entire) substrate.

In a further embodiment, the provided substrate is a semiconductor substrate which comprises a frontside and a backside opposite to the frontside. Furthermore, the etching mask is formed on the frontside of the substrate and substrate material at the frontside of the substrate is removed by carrying out the etching process. The frontside may in this context be the side of the substrate which faces a light radiation during operation of the (finished) solar cell.

In a further embodiment, providing the substrate comprises producing a block or rod of substrate material and carrying out a sawing process in order to form the substrate. The etching process is in this context carried out in order to form the elevated marking structure as well as to remove a sawing damage associated with the sawing process. Such a two-fold use of the etching process conveys high efficiency and economic viability to the solar-cell-marking method. Moreover, the substrate may furthermore be locally “afflicted” by a sawing damage in the area of the marking structure due to the use of the etching mask, which may be favourable for precisely reading out the marking structure. Use may e.g. be made of the fact that the sawing damage in the area of the marking structure causes more scattering during an exposure of the substrate carried out within the framework of a readout. Furthermore, the local sawing damage at the marking structure may cause deviating electrical properties compared to other locations of the substrate, which may e.g. be utilized when reading out the marking within the framework of an electroluminescence or thermography process.

In a further embodiment the etching mask comprises a covering or, respectively, a masking resist. The use of such an etching resist allows for configuring the etching mask on the substrate by means of simple and inexpensive processes, wherein use may be made of the procedures described in the following.

In a further embodiment, the etching mask is formed by means of a jet-printing process. This allows for direct and relatively quick formation of the etching mask.

In a further embodiment, the etching mask is formed by means of a foil transfer process. In such a method, which is direct, as well, a foil comprising the desired etching mask material, e.g. a resist material, may be guided alongside the substrate, and by locally irradiating the foil with a laser, etching mask material may be deposited on the substrate according to the desired structure of the etching mask.

In a further embodiment, forming the etching mask comprises forming a resist layer in a predetermined area or, respectively, partial area on the substrate, and locally irradiating the resist layer. Irradiation may e.g. be carried out by means of a laser beam. In such an embodiment of the method, the resist layer may (also) be formed only locally, which comes along with a saving of costs.

In a further embodiment it is provided that the resist is light-sensitive and locally exposed due to the irradiation. In this embodiment of the method, the resist may either be a negative resist or a positive resist. At this, the local irradiation results in a photochemical reaction in the respective resist and thus in a modification of the stability or, respectively, the solubility. In the case of a negative resist, the solubility decreases as a result of irradiation, whereas the solubility increases in the case of a positive resist.

In an alternative embodiment, the resist is a non-light-sensitive resist which is locally solidified due to irradiation.

When using such resist materials, it is provided according to a further embodiment that forming the etching mask further comprises removing an irradiated or a non-irradiated partial area of the resist layer so that the resist layer is structured to provide the desired etching mask. Removing an irradiated partial area is a consideration in the case of a light-sensitive positive resist for which irradiation results in increased solubility or, respectively, reduced stability (with regard to other non-irradiated areas). Removing a non-irradiated partial area is a consideration in case of a non-light-sensitive resist or in case of a light-sensitive negative resist for which irradiation results in an increased stability or, respectively, reduced solubility (with regard to other non-irradiated areas). The removal of the respective partial area may be carried out by means of a corresponding etching means matched to the respective resist material or, respectively, by means of a developer fluid.

In another embodiment which serves as an alternative for this, an irradiated or a non-irradiated partial area of the resist layer is removed during the etching process carried out in order to form the elevated marking structure. This allows for a relatively quick and economical execution of the method. In this embodiment, the etching mask is produced merely by forming the resist layer and irradiating it locally. Thereby, contrary to the above-described embodiments, the etching mask is not a (physically) structured etching mask but an unstructured etching mask (still) in the form of a layer in which a coding is present in the form of partial areas having different stability or, respectively, solubility. Such an unstructured etching mask, by means of which the marking structure to be generated may be defined (as well), is structured during the etching process carried out in order to form the elevated marking structure.

Forming the resist layer on the substrate may be effected in different ways. A stamp-printing process, a spraying process or a glueing-on of a foil of the resist may for example be carried out for this purpose.

The present invention furthermore provides a solar cell which comprises a substrate and an elevated marking structure on the substrate. The elevated marking structure is formed by carrying out the above-described solar-cell-marking method or, respectively, one of the above-described embodiments, i.e. by carrying out an etching process by means of an etching mask formed on a substrate. Such a marking structure may be produced in a simple and inexpensive manner and moreover allows for reliable and precise reading-out and recognizing of the same.

In a possible embodiment, the substrate of the solar cell is a semiconductor substrate comprising a frontside and a backside opposite to the frontside. The elevated marking structure is formed on the frontside of the substrate or, respectively, forms part of the substrate frontside. In this embodiment the substrate may e.g. be a silicon substrate.

Further embodiments are explained in more detail in conjunction with the accompanying drawings.

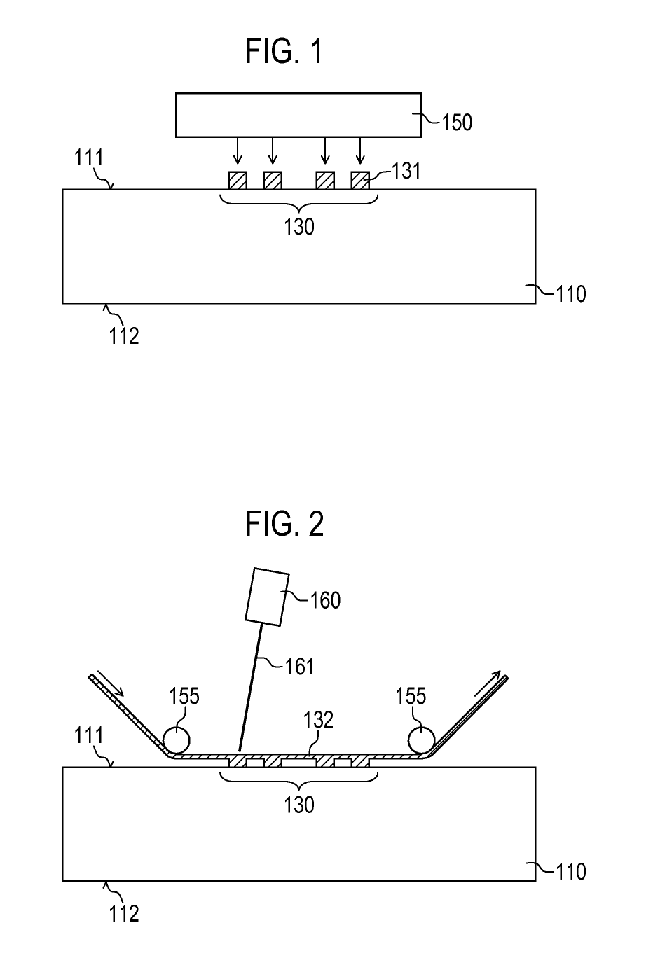

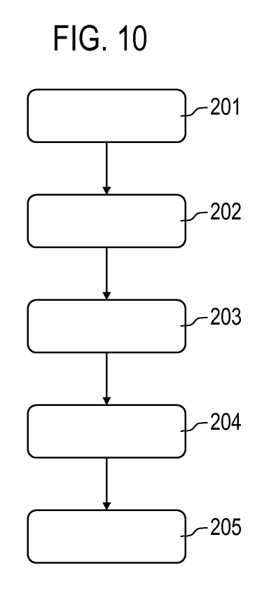

In the following, possible embodiments of a method for producing a solar cell 100, which is provided with an elevated marking structure in an inexpensive and simple manner, are at first described in conjunction with schematic FIGS. 1 to 9. The solar cell 100 depicted in a partial view in FIG. 9 is a wafer-based solar cell comprising a substrate 110 made of a semiconductor material or, respectively, a wafer 110, e.g. made of silicon. Individual steps of the manufacturing method, which will be referred to in the following, as well, are moreover summarized in the flow chart of FIG. 10. It is thereby to be noted that in the course of the method processes known in semiconductor and solar cell technology as well as usual materials may be used, due to which they will only partially be described herein. It is furthermore to be noted that the solar cell 100 depicted in FIG. 9 may comprise further structures and structural elements apart from those shown herein. In the same manner, further method steps in order to complete the solar cell production may be used apart from those depicted and described herein.

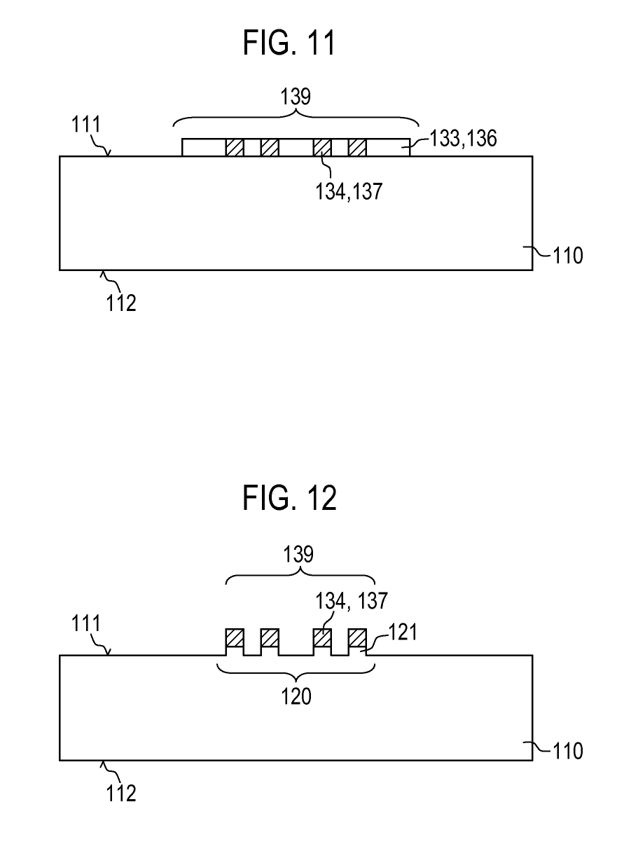

The subsequent FIGS. 11 to 15 illustrate further procedures for providing the solar cell substrate 110 with an elevated marking structure. These alternatives will be referred to in more detail after the following description.

At the outset of the manufacturing method first described in conjunction with FIGS. 1 to 10, a semiconductor substrate 110 depicted in FIGS. 1, 2, 3 is provided in step 201 (cf. FIG. 10), which may e.g. be a silicon wafer. The substrate 110 comprises a frontside 111 and a backside 112 opposite to the frontside 111. In this context, the frontside 111 is the side which faces light radiation (sun light) during operation of the solar cell 100 and by means of which light radiation is injected into the substrate 110. The frontside 111 or, respectively, a corresponding frontside area of the substrate 110 of the solar cell 100 may thus also be referred to as active or, respectively, light-sensitive zone.

Providing the substrate 110 comprises generating a crystal from a semiconductor material or silicon, respectively, e.g. in the form of a block or rod, for which processes such as melting, casting and/or drawing may be used, and sawing the same in order to obtain several individual discs or, respectively, substrates 110. The sawing, which may e.g. be carried out in a wire-sawing process, results in the substrate 110 comprising, particularly at its frontside 111, a sawing damage, i.e. a roughened surface in connection with surface defects or, respectively, impurities (not depicted). Such damage is largely removed by etching (“sawing-damage etch”) at a later process stage.

The provided semiconductor substrate 110 may moreover be provided with a basic doping, for example with a p-conductive basic doping, e.g. boron. Such a doping may already be present in the above-mentioned crystal or, respectively, block or rod made of semiconductor material or it may be introduced into the same within the framework of the manufacturing process, respectively.

In a subsequent step 202 (cf. FIG. 10), an etching mask 130 is formed on the frontside 111 of the substrate 110, the etching mask 130 comprising a predetermined marking pattern.

The etching mask 130 is in this context generated only locally in a partial area of the frontside 111 of the substrate or, respectively, on a small (partial) surface of the frontside 111 of the substrate 110. In order to form the etching mask 130, various processes may be carried out, of which potential examples are described further below in conjunction with FIGS. 1 to 5.

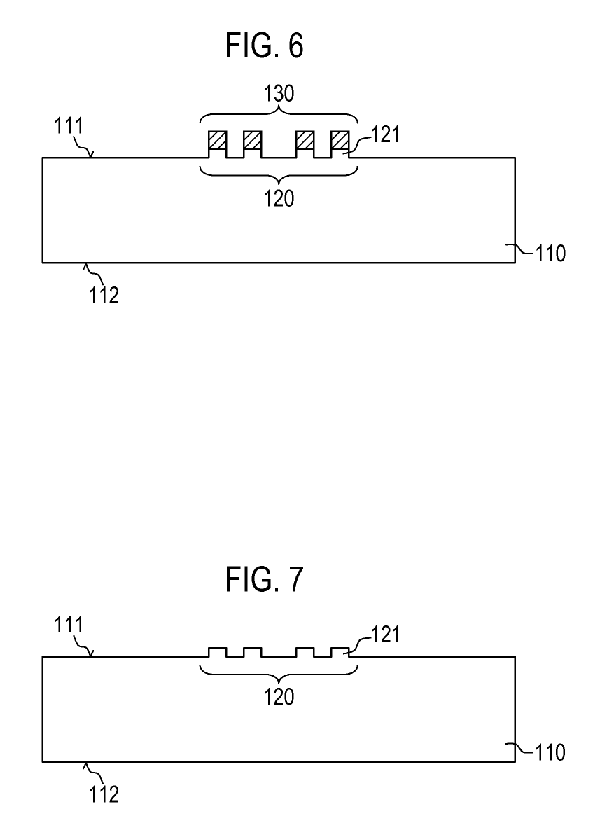

The marking pattern of the generated etching mask 130 is furthermore transferred to the substrate 110 or, respectively, to its frontside 111 within the framework of a subsequent etching step (step 203 in FIG. 10), thus forming an elevated marking structure 120 (“wafer code”) as depicted in FIG. 6, which is configured locally or, respectively, selectively out of the original substrate surface. The marking structure 120, and the etching mask 130, as well, may be used for identifying and tracing the substrate 110 and the associated solar cell 100.

In this context it is to be noted, however, that the elevated marking structure 120 (as well as the etching mask 130) may not only serve and be suitable for identifying, but may be any kind of marking. For example, a configuration or, respectively, use as an alignment mark by means of which various processes are adjusted or, respectively, various process levels are aligned with regard to one another, is possible, as well.

The etching mask 130 which defines the form and the geometry of the marking structure 120 may (in a top view) comprise different structures, signs, symbols and/or code types. Possible examples are a bar code configuration, a matrix or data-matrix code configuration, a configuration as an alpha-numerical serial number comprising numerals and/or letters etc. It is also possible to use a combination of different code types such as a combination of a bar code with a serial number beside it. Instead of separate structures or, respectively, structural elements, the etching mask 130 may also be in the form of a single and/or continuous structure. If the marking structure 120 to be produced (and, as the case may be, the etching mask 130) is to be used as an alignment mark, the etching mask 130 may e.g. be in the form of an alignment cross.

The entire etching mask 130 (and thus the marking structure 120) may e.g. extend over a square or rectangular section of the frontside 111 of the substrate 110 comprising an edge length of e.g. in the centimetre or millimetre range. Individual structures of the etching mask 130 may comprise (horizontal) dimensions, e.g. in the millimetre and micrometre range. Dimensions in the range below a hundred micrometres are conceivable, as well.

The etching mask 130 and as a result the marking structure 120 are moreover formed in an area on the frontside 111 of the substrate 110 in which no frontside finger-shaped contact elements 141 of the solar cell 100 (cf. FIG. 9), which are also referred to as front contacts 141 or “current fingers” 141, are formed. In this context, the etching mask 130 is “positioned” on the frontside 111 of the substrate 110 in such a way that the marking structure 120 defined thereby is arranged between the current fingers 141. In this connection, it may e.g. be provided that the entire marking structure 120 is located between two front contacts 141. Alternatively, the marking structure 120 may also consist of several partial sections or, respectively, partial codes, which are each located between adjacent front contacts 141. For example, the marking structure 120 may consist of several, e.g. four, six or eight, rows of partial sections or partial codes located between adjacent front contacts 141.

As a material for the etching mask 130, use of a resist material is provided which allows for forming of the etching mask 130 on the substrate 110 by means of simple and cost-efficient processes. For the resist material of the etching mask 130, which is stable or, respectively, acid-resistant (or is “rendered” stable) with regard to a (later) forming of the marking structure 120 by means of etching, a plurality of organic photo-, masking, etching or galvanizing resists may be considered. Furthermore, forming such an etching mask 130 may be carried out by means of various direct or indirect methods of which potential embodiments are described in the following in conjunction with FIGS. 1 to 5. Forming the etching mask 130 with the predefined marking pattern is in this context carried out only in a locally limited area or partial section, respectively, on the frontside 111 of the substrate 110.

FIG. 1 shows a direct and quick deposition of the etching mask 130 on the frontside 111 of the substrate 110, carrying out a jet-printing process. In this process, a printing device 150 is positioned in the desired location in the area of the frontside 111 of the substrate 110 and, if applicable, moved alongside the frontside 111 horizontally. The printing device 150 is configured to dispense small amounts of an organic masking resist 131, e.g. by means of nozzles, and, as a result, to locally deposit or, respectively, to print the etching mask 130 having the desired marking pattern onto the frontside 111 of the substrate 110.

The masking resist 131 may e.g. be an alkyl acetate such as ethyl or n-butyl acetate, which for depositing is dissolved in a corresponding solvent, e.g. toluol. After the solvent has dried or volatilized, the etching mask 130 configured from the printed masking resist 131 is finished.

FIG. 2 shows a further direct deposition of the etching mask 130 on the substrate 110 by means of a transfer-foil process. In this context, a foil 132 comprising a resist material or, respectively, coated with a resist material is guided relatively closely along the frontside 111 of the substrate 110 by means of e.g. rolls 155. By locally irradiating the foil 132 by means of a laser beam 161 emitted by a laser device 160, the foil 132 is locally or, respectively, selectively heated, resist material of the foil 132 being thereby applied to or, respectively, deposited on the frontside 111 and the etching mask 130 being generated with the desired marking pattern. In this process, as well, the etching mask 130 is only formed in a locally limited partial section or, respectively, in a partial area on the frontside 111 of the substrate 110.

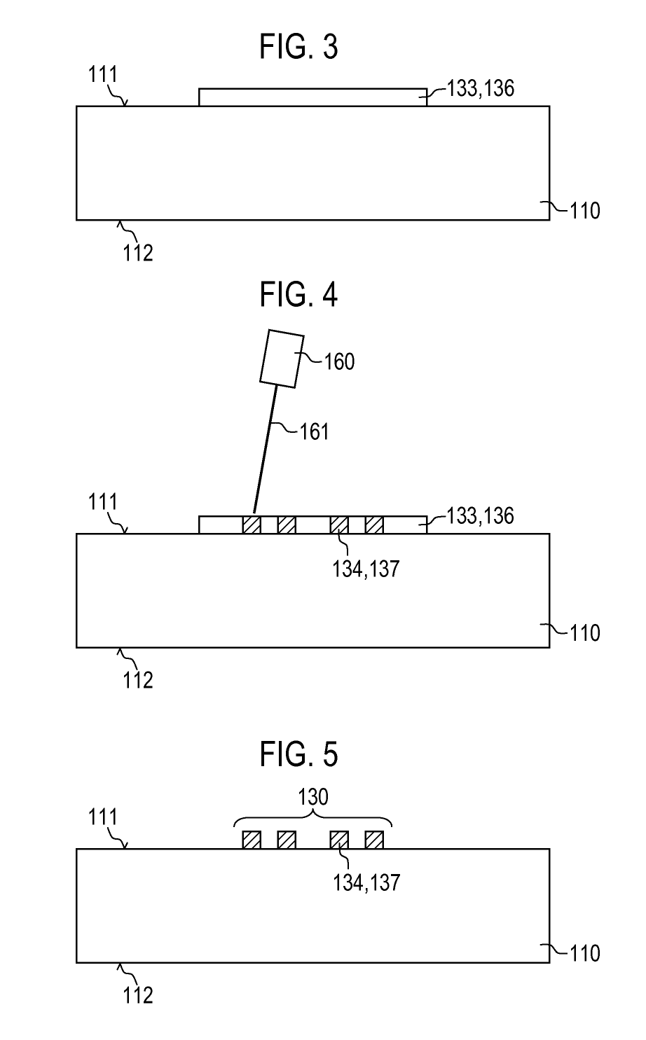

Apart from direct deposition, depositing a marking pattern or, respectively, forming the etching mask 130 may also be carried out indirectly. As depicted in FIG. 3, a layer of a light-sensitive resist 133, also referred to as photoresist, may for this purpose be formed on the frontside 111 of the substrate 110. The resist layer 133, which is formed only partially or, respectively, locally in the area of the subsequently produced etching mask 133 and is therefore arranged on a relatively small surface or, respectively, on a partial section of the frontside 111 of the substrate 110, may for example be printed onto the substrate 110 within the framework of a stamp-printing process. An alternative possibility is spraying-on within the framework of a spraying process. A further possibility is that the layer of the resist 133 is in the form of an adhesive foil or, respectively, a tape comprising the photoresist 133 or consisting of the photoresist 133, which is glued to the frontside 111 of the substrate 110.

Subsequent thereto, as depicted in FIG. 4, selected partial areas 134 of the photoresist layer 133 are selectively exposed or, respectively, irradiated according to the predetermined marking pattern, wherein e.g. a laser beam 161 emitted from a laser device 160 may be used. The exposing of the photoresist 133 in a selective manner comes along with a photochemical reaction and, as a result, with a modification of the stability or, respectively, solubility (with regard to a subsequent structuring process). In case of the embodiment depicted herein, the resist 133 is a negative resist 133 for which the exposure results in an increase of stability or, respectively, decrease of solubility in the exposed partial areas 134.

Depending on the type of photoresist 133 and its sensitivity, exposing may be carried out e.g. by means of a laser radiation in a wavelength range between 300 and 500 nm, for example between 350 and 450 nm. In the time between depositing and structuring the photoresist as described below, no light (apart from the irradiating laser beam 161) of said wavelength range must thus fall onto the photoresist layer 133.

Subsequently, as depicted in FIG. 5, a structuring process for structuring the photoresist 133 and thus to provide the desired etching mask 130 is carried out. For structuring, a developing process may e.g. be carried out in which a corresponding developing solution is used or, respectively, the substrate 110 is treated in a corresponding developing bath. As a result, a non-exposed partial area or, respectively, non-exposed partial areas of the resist 133 which are furthermore soluble, are detached or, respectively, removed from the frontside 111 of the substrate 110. As depicted in FIG. 5, the partial areas 134 which are exposed and comprise low solubility, on the other hand, remain on the frontside 111 of the substrate 110 and form the desired etching mask 130.

Instead of the light-sensitive negative resist 133, the alternative use of a light-sensitive positive resist (not depicted) is possible. A layer of such a positive resist may be printed onto the substrate 110 by means of a stamp-printing process, as well, or be sprayed onto the substrate 110 by means of a spraying process, or be glued onto the substrate 110 in the form of an adhesive foil, and may subsequently be selectively exposed or, respectively, irradiated by a laser beam 161 emitted by a laser device 160. In this context, selective exposure, for which e.g. laser radiation of the ultraviolet wavelength range may be used, also comes along with a photochemical reaction. Contrary to the negative resist 133, however, exposing results in a decrease of stability or, respectively, in an increase in solubility at the respective exposed locations of the positive resist. This property may also be used for forming an etching mask 130 from remaining (in this case non-exposed) partial areas of the positive resist within the framework of a subsequent structuring or, respectively, developing process.

In an alternative indirect embodiment, which is also explained in conjunction with FIGS. 3 to 5, a non-light-sensitive resist 136 or, respectively, a polymer 136 is deposited on the frontside 111 of the substrate 110 instead of a light-sensitive resist (cf. FIG. 3). The resist layer 136 which is only locally formed in a partial area on the frontside 111 of the substrate 110 or, respectively, in the area of the subsequently produced etching mask 133, may again be deposited on the substrate 110, e.g. by means of a stamp-printing process or by means of a spraying process. It is also possible to glue on an adhesive foil comprising the resist 136 or, respectively, consisting of the resist 136 to the frontside 111 of the substrate 110.

Subsequently, as depicted in FIG. 4, selected partial areas 137 of the resist layer 136 are selectively exposed or, respectively, irradiated according to the predetermined marking pattern, which may again be carried out by means of a laser beam 161 emitted by a laser device 160. The selective irradiation of the resist 136 results in a local increase of temperature together with a hardening or, respectively, solidifying, thus forming solidified partial areas 137 of the resist 136.

The solidified partial areas 137 of the heat-sensitive resist 136 are stable with regard to a structuring process carried out subsequently for structuring the resist 136. Said structuring process may e.g. be an etching process in which a corresponding etching liquid is used or, respectively, the substrate 110 is treated in an etching bath. The etching results in only an excessive, non-exposed partial area or, respectively, non-exposed partial areas of the resist 136 being removed from the frontside 111 of the substrate 110, as depicted in FIG. 5. The irradiated and thus solidified partial areas 137, on the other hand, remain on the substrate 110 and form the desired etching mask 130.

After forming the etching mask 130, which may be carried out by means of one of the above-described direct or indirect methods, in a further step 203 (cf. FIG. 10) an etch of the frontside surface of the substrate 110 is carried out, as depicted in FIG. 6. By means of this etching process in which the substrate 110 is e.g. treated in one or several subsequent wet-chemistry-etching baths in order to remove substrate material from the frontside 111 of the substrate 110, the sawing damage caused by the sawing process is remedied.

In this context, an etch removal having a depth or, respectively, height in the range of e.g. several micrometres may take place.

Moreover, the substrate 110 is protected against an etch attack or, respectively, a removal of material in the area of the etching mask 130, which is stable with regard to the etching agent(s) used for the etch. As a result, the sawing-damage etch simultaneously results in the forming of an elevated marking structure 120 defined by the etching mask 130 in the frontside 111 of the substrate 110. The marking structure 120 may comprise or, respectively, represent different structures, signs, symbols and/or code types according to the etching mask 130 (in the top view), which is indicated in the embodiment of FIG. 6 by means of several structural elements or, respectively, elevations 121 protruding (locally) at the frontside 111 of the substrate 110. The marking structure 120 or, respectively, its bumps 121 may comprise a height in the range of e.g. several micrometres according to the etch removal. It is furthermore possible that, contrary to the depiction of FIG. 6, the marking structure 120 or, respectively, the elevations 121 have the form of (partially) under-etched structures.

Instead of separate structures or, respectively, elevations 121, the elevated marking structure 120 may also be configured in the form of a single and/or a continuous structure or, respectively in the form of one single elevation or elevated structure protruding at the frontside 111 of the substrate 110, depending on the configuration of the etching mask 130. In case of the marking structure 120 being configured as an alignment mark, the marking structure 120 may be in the form of an alignment cross protruding at the frontside 111.

Due to the dual use of the sawing-damage etch for remedying the sawing damage as well as for forming the elevated marking 120, high efficiency and economic viability may be achieved. Furthermore, although it is true that the sawing damage at the frontside 111 of the substrate is largely removed, the substrate 110 still comprises sawing-damage defects and a roughened surface (not depicted) at the marking structure 120 or, respectively, at the elevations 121 due to the etching mask 130 having a protecting or, respectively, masking effect. This factor may be utilized for precisely reading out the marking structure 120, as will be described further below.

After the sawing-damage etch and the generation of the elevated marking structure 120, the etching mask 130 is removed in a further step 204 (cf. FIG. 10), thus exposing the frontside 111 of the substrate 110 comprising the marking structure 120, as depicted in FIG. 7. By this, it may be avoided that the etching mask 130 or, respectively, its material causes a contamination of the substrate 110 in a subsequent process.

In order to remove the etching mask 130, a high-temperature step may e.g. be carried out in which the substrate 110 is treated with a plasma in order to thermally remove or, respectively, vaporize the etching mask 130 (“plasma asking”). Alternatively, the etching resist or, respectively, the etching mask 130 may be removed chemically, e.g. by means of a corresponding solvent.

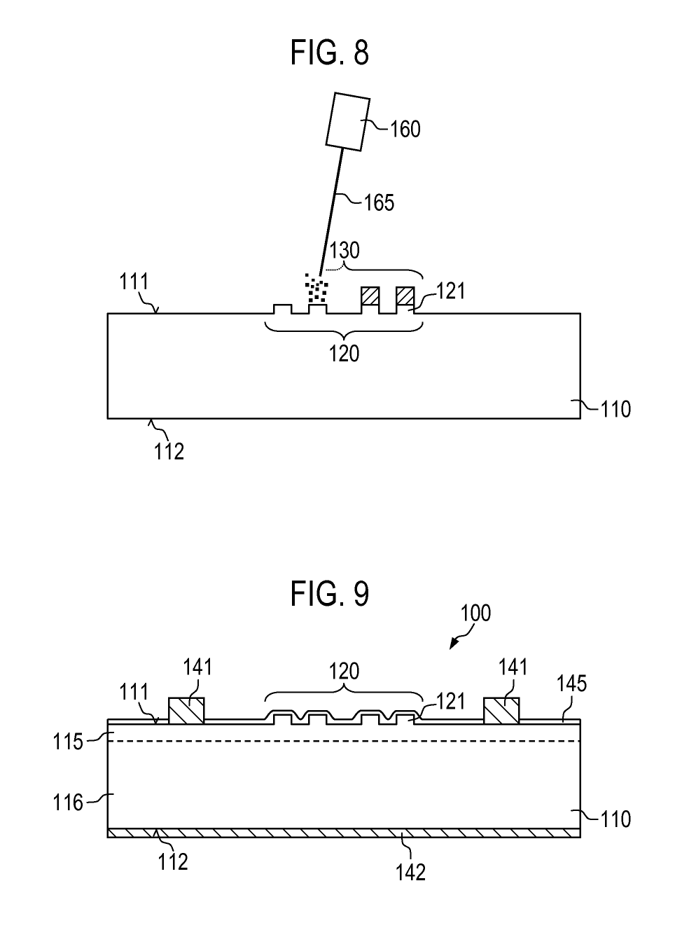

In a further alternative process which is depicted in FIG. 8, on the other hand, a surface clean of the substrate 110 is carried out by using a laser beam 165 emitted from a laser device 160, e.g. a pulsed laser beam 165, only in the region of the etching mask 130. At this location, the laser beam 165 is directed to the frontside 111 of the substrate 110 and guided along the frontside 111, by which removing or, respectively, vaporizing of the etching mask 130 may be achieved, as well. This local method, in which contrary to the abovedescribed procedures not the entire substrate 110 is “treated”, is more economical and may further be carried out relatively quickly. Moreover, thermal stress acting on the (entire) substrate 110 may be avoided.

Subsequently, further processes for finishing the solar cell 100 depicted schematically and in part in FIG. 9 are carried out. These processes are summarized in a step 205 in the flow chart of FIG. 10.

Step 205 e.g. includes the processing of the substrate 110 in such a way that the substrate 110 comprises regions 116, 115 of different conductivity, also referred to as “base” 116 and “emitter” 115, and as a result comprises a p-n junction. For this purpose, the substrate 110 already provided with a p-conductive basic doping may be subjected to a diffusion process, resulting in a (thin) region in the area of the (frontside) surface being provided with an n-doping, and an emitter-base structure (p-type base 116, n-type emitter 115) or, respectively, a p-n junction in the substrate 110 being formed as a result. This may e.g. be carried out by processing the substrate 110 in a furnace having a phosphoric atmosphere.

By means of the p-n junction, an inner electric field is generated in the substrate 110. During operation of the solar cell 100, a separation of free charge carriers may in this way be achieved, which are generated within the substrate 110 during irradiation of the solar cell 100 by means of light due to radiation absorption. In this context, the solar cell 100 is aligned in such a way with regard to the light radiation that the frontside 111 of the substrate 110 faces the light.

Within the framework of step 205, forming a translucent antireflection layer 145 on the frontside 111 of the substrate 110 is furthermore provided, by means of which a reflection of radiation occurring at the frontside 111 and yield losses connected thereto may be reduced. The antireflection layer 145, which also covers the marking structure 120, as depicted in FIG. 9, may e.g. comprise silicon nitride and is e.g. deposited on the frontside 111 of the substrate 110 by means of a plasma enhanced chemical vapour deposition (PECVD).

In order to complete the solar cell 100 of FIG. 9, a number of finger-shaped (and thus causing little shadowing effects) front contacts 141 at the frontside 111 and a plane back contact 142 at the backside 112 of the substrate 110 are formed by means of which the base 116 and the emitter 115 and thus the poles of the p-n junction may be contacted for energy and current generation during operation of the solar cell 100. The front contacts 141 of which only two are depicted in the sectional view of FIG. 9, at this extend through the antireflection layer 145 to the substrate 110 or, respectively, to the emitter 115.

Forming of the front contacts 141 and of the back contact 142 may be carried out in different ways. For example, an electrically conductive or, respectively, metallic paste (e.g. aluminium paste) may be printed onto the antireflection layer 145 in order to form the front contacts 141 (including contact pads or, respectively, soldering pads). On the backside 112 of the substrate 110, as well, such a paste may be printed on over a large area in order to form the back contact 142. By means of a subsequent temperature or, respectively, sintering process also referred to as firing step, the printed contact elements 141, 142 are connected to the substrate 110. In this context, the frontside contact elements 141 are connected to the substrate 110 through the antireflection layer 145 (“fire-through process of the contacts”).

In the area of the backside 112, the firing step may further result in a diffusion of a portion of the metallic paste (aluminium atoms) into the substrate 110, thus forming what is referred to as a back-surface field (BSF). Such a backsurface field acts as a mirror at which generated charge carriers are reflected, as a result of which recombination losses may be reduced.

As already discussed above, the marking structure 120 is formed in an area on the frontside 111 of the substrate 110 in which no front contacts or, respectively, current fingers 141 are formed. It may be provided that the entire marking structure 120 is located between two front contacts 141, as indicated in FIG. 9. Alternatively, the marking structure 120 may also consist of several partial sections or, respectively, partial codes which are each located between adjacent front contacts 141. This embodiment reduces the probability of (incorrectly) forming the front contacts 141 on the marking structure 120 or, respectively, of overprinting the marking structure 120 by one or, respectively, several front contacts 141.

The marking structure 120 formed at the substrate 110 of the solar cell 100, and also the etching mask 130 defining the marking structure 120 may be used to allow for a reliable and precise identification and tracing of the substrate 110 or, respectively, of the solar cell 100. Such an identification is possible at various stages of manufacturing as well as after manufacturing up to the completed solar module, in which several of such solar cells 100 have been connected.

For reading out, the elevations 121 of the marking structure 120 (or, respectively, the structural elements or, respectively, “etch-resist dots” of the etching mask 130) may be rendered visible by means of a suitable method (e.g. illuminating the frontside 111) and a corresponding image may be taken with a camera (e.g. a charge-coupled device camera, CCD), the image being further processed in order to recognize the associated coding. In this connection, known methods of text recognition or, respectively, optical character recognition (OCR) may be carried out, which will not be further described herein.

For rendering the marking structure 120 or, respectively, the etching mask 130 visible, the approaches described in the following may be taken. In this context, use may be made of the fact that, contrary to the rest of the substrate surface, the marking structure 120 is “afflicted” with sawing damage.

It is e.g. possible to read out a coding of the substrate 110 in a stage in which the substrate 110 is (still) provided with the etching mask 130, which is possible in the “as deposited” phase of the “raw wafer” or, respectively, before the generation of the actual marking 120 by means of etching, as well as after generating the marking 120. In order to render the etching mask 130 visible, e.g. the frontside 111 of the substrate 110 may be illuminated by means of an ultraviolet radiation, and an image of the radiation reflected at the frontside 111 may be taken (“incident-light image”). However, it is also possible that a dye is added to the material or, respectively, to the resist material of the etching mask 130 so that the etching mask 130 may be read out in a “normal” incident-light image, i.e. when illuminating the substrate 110 with radiation of the visible wavelength range.

After carrying out the sawing-damage-etching step and forming the marking structure 120, the sawing damage remains below the etching mask 130 or, respectively, below the associated “etch-resist dots”. Prior to or after removing the etching mask 130, the marking structure 120 may be made visible by illumination, while the sawing damage (roughened surface) may cause an increased scattering, contrary to the rest of the substrate surface. For this reason, the marking structure 120 is recognizable not only due to scattering effects at the individual elevations 121 and a contrast caused thereby, but additionally due to the increased scattering caused by sawing damage.

In this respect, a transmission illumination using a near-infrared radiation (NIR) may e.g. be carried out for reading out, wherein the frontside 111 of the substrate 110 is irradiated and a portion of the radiation emitted at the backside 112 and transmitted through the substrate 110 (NIR transmission image) is detected by means of a corresponding camera. Here, the locations of the marking structure 120 appear dark due to the stronger scattering caused by the sawing damage.

Due to scattering, the marking structure 120, however, is well recognizable as well during illumination of the frontside 111 and detection of the reflected radiation or, respectively, of the incident-light image. For illuminating, light of the visible wavelength range or NIR radiation may be utilized.

In order to render the marking structure visible, a light-scatter illumination (dark field illumination) may be carried out, as well. At this, the dots or, respectively, elevations 121 of the marking structure 120 appear bright.

The sawing damage in the area of the marking structure 120 may further result in the solar cell 100 or, respectively, its p-n junction having different electrical properties at this location. This may e.g. be caused by impurities which have not been etched off, but also by an emitter 115 having less electrical conductivity in the area of the marking structure 120. This property may be utilized in further camera-based methods.

One method is e.g. what is referred to as electroluminescence, in which an electrical voltage or, respectively, a forward voltage is applied to the solar cell 100, the solar cell 100 being as a result stimulated to emit an electromagnetic radiation (particularly NIR radiation). An alternative method is what is referred to as photoluminescence in which the solar cell 100 is stimulated by irradiation (e.g. by means of a laser) to emit radiation. The weaknesses in the electrical properties in the area of the marking structure 120 may for both processes result in lower radiation emission in the area of the marking structure 120 when compared to the rest of the substrate surface. This may be detected by means of a corresponding camera or, respectively, a CCD camera.

A further comparable method is what is referred to as serial-resistance imaging in which the solar cell 110 is stimulated to emit radiation by means of different current feeds, wherein the occurring and detected emission images are combined with and offset against each other. In this connection, as well, the marking structure 120 may be recognized due to the “different” emission behaviour occurring at this location.

Moreover, thermographical methods may be carried out. In this context, the solar cell 100 is stimulated to generate a thermic image which may be recorded by an infrared or, respectively, a thermic image camera.

A possible method is what is referred to as dark lock-in thermography in which the solar cell 100 is stimulated by applying an electrical forward voltage. In this context, the marking structure 120 or, respectively, the sawing damage at this location causes a local or, respectively, locally increased heating so that the marking structure 120 may be recognized in a recorded thermic image. A comparable thermographical method is a lock-in thermography with illumination in which the stimulation of the solar cell 100 for generating a thermic image is effected by means of e.g. an arrangement of light emitting diodes.

In order to carry out such methods, corresponding devices or, respectively, measuring stations may be provided at classifiers by means of which testing and classifying of solar cells 100 or, respectively, solar cell substrates 110 is carried out. A method based on electroluminescence may be carried out in a relatively short measuring period of less than one second, e.g. in 0.5 seconds. This is due to the fact that a stimulation of a solar cell 110 for emitting a radiation may be achieved faster than a (local) heating of a solar cell 110.

Apart from the use as an identifying structure, any other use of the marking structure 120 (as well as of the etching mask 130, if applicable) is alternatively possible, as described above. An example is a use as an alignment mark by means of which various manufacturing processes carried out on the substrate 110 may be adjusted to one another. In the case of such a use (or a different one), the above-described approaches may be employed, as well, for rendering visible and recognizing the marking structure 120 or, respectively, the etching mask 130.

Apart from the above-described procedures and methods, a marking of the substrate 110 of the solar cell 100 may also be carried out in a different manner, as is described in the following in conjunction with FIGS. 11 to 15. It is thereby to be noted that reference is made to the above description with regard to already described details which e.g. refer to feasible comparable process steps, suitable materials, possible advantages, reading out of a marking, a configuration of a marking in the form of a sign, symbol or as an alignment mark etc.

FIGS. 11 and 12 depict the forming of an elevated marking structure 120 on the frontside 111 of the substrate 110, wherein instead of a structured etching mask 130 an unstructured etching mask or, respectively, etching-mask layer 139 is utilized, in which a marking pattern or, respectively, a coding is present in the form of partial areas having differing stability or, respectively, solubility, and not in the form of a “physical” structure. Such a property may be realized by means of corresponding resist or, respectively photoresist materials.

As depicted in FIG. 11, the unstructured etching mask 139 may e.g. be a layer of a light-sensitive negative resist 133 comprising partial sections 134 which are selectively exposed and, as a result, comprise higher stability or, respectively, lower solubility. Alternatively, the unstructured etching mask 139 may also be a layer of a heat-sensitive resist 136 in which partial sections 137 are selectively irradiated and thus solidified. A further non-depicted alternative is a configuration of the etching mask 139 as a layer of a lightsensitive positive resist having areas which are partly exposed and thus comprise lower stability.

In order to form the etching mask 139 with differing “stability” (step 202 in FIG. 10), wherein the etching mask 139 again only extends over a small partial area of the frontside 111 of the (provided) substrate 110, the procedures described above with reference to FIGS. 3 and 4 may be used.

Subsequent thereto, the frontside surface of the substrate 110 is etched (step 203 in FIG. 10). In this way, the etching mask 139 is simultaneously structured so that—as depicted in FIG. 12—only the stable partial areas 134, 137 of the etching mask 139 remain. The etch may be the sawing-damage etch carried out in order to remove sawing damage, in which the substrate 110 is e.g. treated in one or several subsequent wet-chemistry baths or, respectively, etching baths. With regard to a configuration of the etching mask 139 in the form of a light-sensitive photoresist, e.g. the shown negative resist 133, the etching procedure represents a developing procedure of the photoresist in question.

In the course of the etch, the substrate 110 is protected from an etch attack or, respectively, material removal in the area of the stable partial sections 134, 137 of the etching mask 139, which “comprise” the desired marking pattern, so that an elevated marking structure 120 defined by the etching mask 139 is (again) formed in the frontside 111 of the substrate 110. As indicated in FIG. 12, said marking structure 120 may e.g. be provided in the form of several structural elements or, respectively, elevations 121 (locally) protruding at the frontside 111 of the substrate 110. Due to the protective or, respectively, masking effect of the partial sections 134, 137 of the etching mask 139, the substrate 110 may still comprise sawing-damage defects and a roughened surface at the marking structure 120 or, respectively, at the elevations 121 (not depicted), which may be utilized in order to precisely read out the marking structure 120, as described above.

Since in this embodiment of the method a separate structuring of the etching mask 139 is omitted and the etching mask 139 is structured within the framework of etching to form the marking 120, it is possible to carry out the method relatively quickly and in an economic manner. After forming the marking 120, the above-described steps (removing the stable partial sections 134, 137 of the etching mask 139 or, respectively, step 204, carrying out further processes in order to complete the associated solar cell 100 or, respectively, step 205) may be carried out in an analog manner. For details, reference is made to the above description.

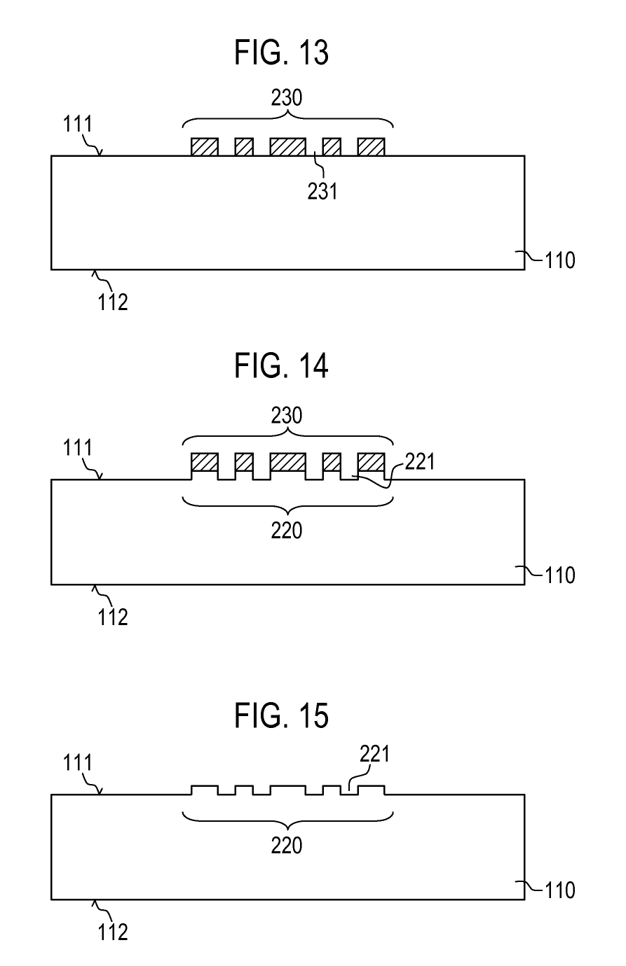

In the above-described embodiments, the generated elevated marking structure 120 is present in the form of one or several elevations 121 directly representing the corresponding “code”. As an alternative, however, it is also possible to form a “reversed” or, respectively, inverse elevated marking structure 220 in which the coding is present in the form of one or several recesses 221 instead of one or several elevations 121. This is described in more detail in the following with reference to FIGS. 13 to 15.

In order to generate the inverse marking structure 220, a structured etching mask 230 may again be formed on the frontside 111 of the (provided) substrate 110 with a predetermined marking pattern (step 202 in FIG. 10), the etching mask 230 only covering a (small) partial area of the frontside 111 of the substrate 110, as depicted in FIG. 13. Contrary to the above-described etching mask 130 in which the marking structure in question is directly represented or, respectively, the corresponding “code” is directly configured in the form of one or several elevated structural elements, the marking pattern of the etching mask 230 is formed inversely thereto. The inverse etching mask 230 thus comprises an elevated basic structure comprising one (single or, respectively, continuous) hollow 231 or several hollows 231. At this, one or several hollows 231 may be provided within the basic structure or extend to a(n) (outer) border of the basic structure so that the basic structure is “open” at its border. In this connection, the frontside 111 of the substrate 110 is exposed in the area of the hollow(s) 231 and the marking pattern is represented in the form of the hollow(s) 231.

The basic structure of the etching mask 230 in which the hollow(s) 231 has/have been formed may have any desired outline (in the top view). One example is a rectangular or square outline with an edge length of e.g. in the centimetre or millimetre range. For the hollow(s) 231, the above-indicated structures (e.g. bar code, matrix or, respectively, data-matrix codes, alphanumerical serial number with numerals and/or letters, alignment mark etc.) as well as the abovementioned dimensions (e.g. in the millimetre or the micrometre range) may be provided. In the same manner, the abovementioned resist materials may be used and the abovedescribed methods (direct deposition or indirect forming) may be carried out in order to form the etching mask 230. With regard to further details on this, reference is made to the above description.

After forming the inverse etching mask 230, the frontside surface of the substrate 110 is etched (step 203 in FIG. 10) so that, as depicted in FIG. 14, an elevated marking structure 220 defined by the (stable) etching mask 230 is formed in the frontside 111 of the substrate 110. The etch may be the sawing-damage etch carried out in order to remove sawing damage, in which the substrate 110 is e.g. treated in one or several subsequent wet-chemistry baths or, respectively, etching baths.

In accordance with the etching mask 230, the marking structure 220 comprises a basic structure which is elevated with regard to the surrounding substrate area and in a top view comprises any desired outline, e.g. a rectangular or square outline with an edge length e.g. in the centimetre or millimetre range. The basic structure is furthermore provided with one (single or, respectively, continuous) recess 221 or, respectively, several recesses 221, which is defined by the form and position of the hollow(s) 231 of the etching mask 230. In this respect, one or several recess(es) 221 of the marking structure 220 may be provided within the elevated basic structure or extend to a(n) (outer) border of the basic structure so that the basic structure is “open” at the border. In the same manner, the recess(es) 221 may be in the above-described forms (e.g. bar code, matrix or, respectively, data-matrix codes, alphanumerical serial number with numerals and/or letters, alignment mark etc.) and dimensions (e.g. in the millimetre or the micrometre range).

Due to the protective effect of the etching mask 230, the substrate 110 may again comprise sawing-damage defects and a roughened surface in the area of the marking structure 220, which may be utilized for precise reading-out of the marking structure 220. Contrary to the marking structure 120, in case of the inverse marking structure 220 the sawing-damage defects are not present in the actual marking pattern, i.e. in the recess(es) 221, but the marking pattern is surrounded by a “sawing-damage pattern” (non-etched region of the basic structure).

After forming the inverse marking 220, the etching mask 230 may be removed, as depicted in FIG. 15 (step 204 of FIG. 10). Moreover, further processes may be carried out in order to complete an associated, non-depicted solar cell comprising the inverse marking 220 (step 205 in FIG. 10). For details on this, reference is made to the above description.

In the production of the inverse marking structure 220, as well, an unstructured etching mask may be used instead of the shown and described structured etching mask 230, in which an (inverse) coding is not present in the form of a “physical” structure but in the form of partial regions having different stability or, respectively, solubility. In this context, the areas “representing” the predetermined marking structure are soluble with regard to other areas of the etching mask. In such an embodiment, as well, the approaches described above in conjunction with FIGS. 11 and 12 may be used in an analogous manner.

The embodiments described with reference to the Figures represent exemplary embodiments of the invention. Apart from the described and depicted embodiments, other embodiments are conceivable which may comprise further modifications or, respectively, combinations of features.

A marking structure or, respectively, a wafer code 120, 220 (provided in the area of a light-sensitive region) may be realized with other dimensions and structures than those described above. Also, other processes than those described above may be used. Among these processes is e.g. a heating step carried out for baking a resist or, respectively, photoresist or, respectively for driving a solvent out of a resist material.

Furthermore, a solar cell 100 provided with an elevated marking structure 120, 220 may be formed with materials different from those mentioned above. This is e.g. true for an antireflection layer 145 as well as for frontside and backside contact elements 141, 142. Also, the base 116 and the emitter 115 of a solar cell 100 may be formed with inverted conductivities, i.e. an n-type base 116 and a p-type emitter 115.

Moreover, a solar cell 100 provided with an elevated marking structure 120, 220 may comprise other or additional structures and structural elements, which may (also) come along with carrying out further processes than those described. It is e.g. conceivable to additionally provide a backside of a solar cell substrate 110 with a dielectric passivation layer (“backside passivation”). This may also be carried out after forming a p-n junction in the substrate 110.

A further alternative is providing a frontside 111 of a substrate 110 with a textured surface, thus reducing or, respectively, suppressing a reflection of light radiation at the frontside 111 and (also) the yield losses associated herewith. Such a surface structure or, respectively, texture may e.g. be formed within the framework of a sawing-damage etch or in a further etching process. In this regard, it is possible that a marking structure 120, 220 produced on a solar cell substrate 110 is provided with or without a texture. This depends on whether the forming of the texture is carried out prior to or after removal of an etching mask (provided for generating the marking structure 120, 220). In case of the marking structure 120, it may be provided that e.g. only the elevation(s) 121 are not provided with a texture, whereas other areas (between the elevations 121) and the substrate surface surrounding the marking structure 120 are provided with a texture. In case of the inverse marking structure 220, e.g. an (elevated) area arranged around one or several recesses 221 may be provided without a texture, and the recess(es) 221 and the substrate surface surrounding the marking structure 220 may be provided with a texture. This may make it possible to further favourably influence a precise reading-out process or, respectively, a process of rendering visible the marking structure 120, 220 (due to the higher reflection at locations without texture).

A further modification is to form finger-shaped contact elements or, respectively, current fingers (as on the frontside 111) also on a backside 112 of a substrate 110 of a solar cell 100 instead of a plane backside contact 142. Such an embodiment may e.g. be considered for a bifacial solar cell.

Moreover, a (provided) substrate 110 of a solar cell 100 may comprise another semiconductor material than silicon (such as cadmium-telluride, a copper compound, etc.), consist of several different layers or, respectively, materials and/or be provided in a manner different from forming a semiconductor crystal and sawing it. For example, a semiconductor substrate 110 may be directly generated by means of a corresponding method or a substrate 110 may be directly generated within the framework of thin-film techniques (“thin-film cell”). In such embodiments, as well, a forming of an elevated marking structure 120, 220 may be carried out by means of the above-described approaches by forming an etching mask on the substrate 110 and carrying out an etching process.

Moreover, an etching mask provided for forming an elevated marking structure 120, 220 may be configured of other than the above-named materials or, respectively, resist materials. For example, an etching mask may comprise a hard-mask material based e.g. on carbon or silicon.

Furthermore, it is to be noted that the forming of a marking structure 120, 220 by etching using an etching mask is also possible in a different or, respectively, later process stage of the manufacture of a solar cell 100. For example, marking of a substrate 110 may not take place until a p-n junction is formed in the substrate 110.

It is furthermore to be noted that a “locally elevated” marking or, respectively, a wafer code 120 as well as a marking 220 which is inverse thereto may be formed on a substrate 110 plurally or, respectively, redundantly in order to allow for reliable distinction of the marking 120, 220 from other inhomogeneities of the solar cell 100 or, respectively, of the substrate 110.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

1. A solar-cell-marking method comprising the steps of:
providing a substrate for a solar cell;
forming an etching mask on the substrate; and
carrying out an etching process, wherein an elevated marking structure defined by the etching mask is formed on the substrate.

2. The solar-cell-marking method according to claim 1, further comprising removing the etching mask after carrying out the etching process.

3. The solar-cell-marking method according to claim 2, wherein removing the etching mask is effected by irradiating the etching mask with a laser beam.

4. The solar-cell-marking method according to claim 1,
wherein the provided substrate is a semiconductor substrate and comprises a frontside and a backside opposite to the frontside,
wherein the etching mask is formed on the frontside of the substrate,
and wherein substrate material at the frontside of the substrate is removed by carrying out the etching process.

5. The solar-cell-marking method according to claim 1, wherein providing the substrate comprises producing of a block or rod of substrate material and carrying out a sawing process in order to form the substrate, and wherein the etching process is carried out in order to form the elevated marking structure as well as to remove a sawing damage associated with the sawing process.

6. The solar-cell-marking method according to claim 1, wherein the etching mask comprises a resist.

7. The solar-cell-marking method according to claim 1, wherein the etching mask is formed by means of a jet-printing process.

8. The solar-cell-marking method according to claim 1, wherein the etching mask is formed by means of a foil transfer process.

9. The solar-cell-marking method according to claim 1, wherein forming the etching mask comprises the steps of:
forming a resist layer in a predetermined area on the substrate; and
locally irradiating the resist layer.

10. The solar-cell-marking method according to claim 9, wherein the resist is light-sensitive, and wherein the resist is exposed locally due to the irradiation.

11. The solar-cell-marking method according to claim 9, wherein the resist is not light-sensitive, and wherein the resist is solidified locally due to the irradiation.

12. The solar-cell-marking method according to claim 9, wherein forming the etching mask further comprises removing an irradiated or a non-irradiated partial area of the resist layer.

13. The solar-cell-marking method according to claim 9, wherein an irradiated or a non-irradiated partial area of the resist layer is removed during the etching process carried out in order to form the elevated marking structure.

14. The solar-cell-marking method according to claim 9, wherein forming the resist layer on the substrate is effected by one of the following steps:
carrying out a stamp-printing process;
carrying out a spraying process; or
glueing-on a foil of the resist.

15. A solar cell comprising:
a substrate; and
an elevated marking structure on the substrate, formed by carrying out an etching process by means of an etching mask formed on the substrate.

16. The solar cell according to claim 15,
wherein the substrate is a semiconductor substrate and comprises a frontside and a backside opposite to the frontside,
and wherein the elevated marking structure is formed on the frontside of the substrate.
